(19) United States
(12) Patent Application Publication
(10) Pub. No.: US 2018/0198379 A1
(43) Pub. Date: Jul. 12, 2018

(54) POWER CONVERTER FOR OUTDOOR USE

(71) Applicant: POWER ELECTRONICS ESPAÑA, S.L., Patema / Valencia (ES)

(72) Inventors: David SALVO LILLO, Paterna (ES); Abelardo SALVO LILLO, Paterna (ES); Antonio POVEDA LERMA, Paterna (ES)

(73) Assignee: Power Electronics España, S.L., Paterna / Valencia (ES)

(21) Appl. No.: 15/741,631

(22) PCT Filed: Jun. 7, 2016
(86) PCT No.: PCT/ES2016/070508

§ 371 Date: Jan. 3, 2018

(30) Foreign Application Priority Data
Jul. 29, 2015 (ES) P201531131

(51) Int. Cl. H02M 7/00; H02B 1/56; H05K 7/20

(52) U.S. Cl. CPC H02M 7/003; H05K 7/2089; H02B 1/565

(57) ABSTRACT

The invention relates to a power converter for outdoor use comprising at least a first cabinet having an air inlet (1) and a second cabinet having an air outlet (2) that surround a cell cabinet (3) having a plurality of power cells (3a) and a transformer cabinet (4) with at least one power transformer (4a); and wherein the air inlet (1) comprises a sand trap (5); a cold air stream (9) from outside the converter passes from the air inlet (1) to the cells (3a) and the transformer (4a) through a cyclonic air filter (6) comprising a tubular duct with an inner geometry formed by helical-shaped blades; and wherein a warm air stream (10) from the cells (3a) and the transformer (4a) is expelled through the air outlet (2).

### FIELD OF INVENTION

The object of the present invention relates to a power converter for the outdoors (known in the sector as “outdoor” power converters) which is encompassed in the field of energy generation and require a power converter that cannot be installed in a room, i.e., that is located in the open air.

### BACKGROUND

The main technical problem faced by power converters installed outdoors is that, given that they are located in the open air, they are exposed to different atmospheric agents (rain, wind, snow or any other agents) which cause corrosion or lead to operation failures due to the presence of sand in the air, moisture or directly water.

To prevent these operational problems, power converters for the outdoors consist either of power converters designed for the indoors contained in concrete containers or housings, or of converters with a special liquid cooling for the outdoors. The first of these solutions has problem in terms of cooling which is performed through air-conditioning, that entails a large size, constant maintenance and problems in terms of efficiency and complexity. The second solution makes the solution significantly more expensive.

US patent document U.S. Pat. No. 3,364,838 is known in the state of the art, said document describing a power converter for outdoor use comprising several cabinets: a cabinet having an air inlet, a cabinet having an air outlet, a power cell cabinet and a transformer cabinet, wherein the air inlet comprises a sand trap and a cyclonic air filter.

Said document furthermore describes that said converter comprises a helical-shaped tubular duct through which the air passes driven by an associated centrifugal fan.

The main difference between said document and the present invention is that the present invention incorporates a tubular duct with an inner geometry formed by helical-shaped blades and the warm air is furthermore expelled through an upper duct. This means that the cyclonic air filters incorporated in the present invention do not require maintenance (whereas this would not be the case in the US patent document) and they filter the incoming air, using it in turn for cooling the converter.

### SUMMARY

The object of the present invention relates to a power converter which, for the use thereof outdoors, does not require insertion in concrete containers or housings. This represents significant advantages over the state of the art that has been described, since the proposed solution has a small size, does not require maintenance as it is much less complex and, is furthermore more efficient from the converter operation viewpoint.

This object is achieved with the converter described in the independent claim accompanying the present specification and incorporated in this section by reference. Likewise, the dependent claims describe particular embodiments of the invention that are incorporated in the present section also by reference.

The power converter object of the invention essentially comprises cooling means including inside the shell thereof sand traps and cyclonic air filters arranged such that they do not require maintenance, filter the incoming air and use said air for cooling the converter, thereby achieving the proposed objects.

Throughout the description and the claims, the word “comprises” and variants thereof do not intend to exclude other technical features, supplements, components or steps, for the persons skilled in the art, other objects, advantages and features of the invention will be inferred in part from the description and in part from the practice of the invention. The following examples and drawings are provided by way of illustration and they are not meant to limit the present invention. Furthermore, the present invention cover all the possible combinations of particular and preferred embodiments herein indicated.

### BRIEF DESCRIPTION OF THE DRAWINGS

A series of drawings which aid to better understand the invention and are expressly related to an embodiment of said invention presented as a non-limiting example thereof will be briefly described below.

FIG. 1 shows a front view of the power converter object of the invention.

FIG. 2 shows a horizontal section A-A of the top view of the converter of FIG. 1.

FIG. 3 shows the section of FIG. 2 depicting the air extraction duct.

FIG. 4 shows the section of FIG. 2 depicting the airflow inside the converter.

### DETAILED DESCRIPTION

FIG. 1 shows an embodiment of the power converter object of the invention, incorporating a first cabinet having an air inlet (1) and a second cabinet having an air outlet (2) that surround a cell cabinet (3) and a transformer cabinet (4) such as the one described in the current state of the art.

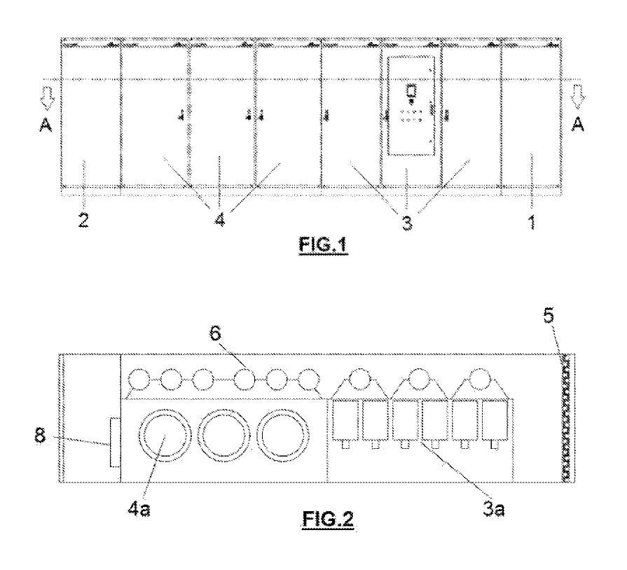

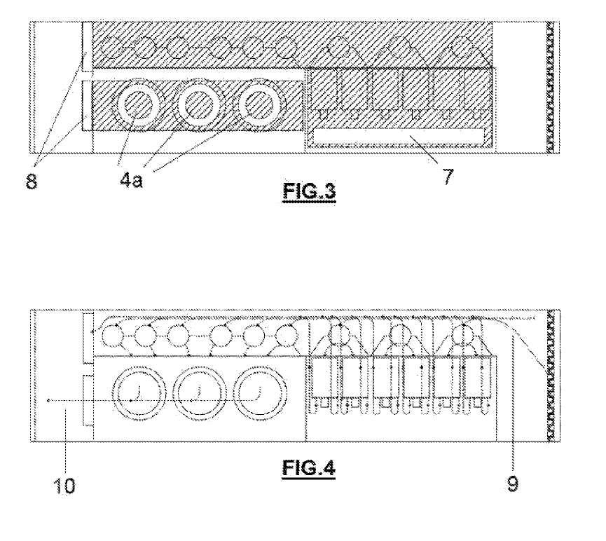

The novelty and usefulness of the power converter object of the invention lies in the cooling design of the converter, as best seen in FIGS. 2 and 3. In this sense, there is incorporated in the first cabinet having an air inlet (1) a sand trap (5) which prevents the passage of coarse particles into the dirty area of the equipment, i.e., to the cells (3a) and therefore, to the transformer (4a),

The air at the inlet of the cells (3a) and the transformer (4a) is filtered by means of cyclonic air filters (6) that prevent the entry of particles in the air since they are tubular ducts with a specific inner geometry, basically helical-shaped blades, which causes, as the air passes through said blades, the dirt present in the air to be centrifuged therein, being collected through a duct and expelled to the outside. The air at the outlet of the cyclonic air filters (6) is therefore free of impurities and can cool both the cells (3a) and the transformer (4a). In the cyclonic air filters (6), the air is driven by means of centrifugal fans associated therewith. Finally, warm air is expelled through an upper duct (7) incorporating at least one fan (8) be it an axial fan, a centrifugal fan or another type of fan.

The airflow is depicted in FIG. 4 by means of a dashed line, showing how the air enters through the sand trap (5) integrated in the air inlet (1). The airflow then goes to the cyclonic filters (6) through which clean and cold air (9) will pass to the power cells (3a) located in a leak-tight area (the cell cabinet (3)) and to the transformer (4a). The warm air (10) passing through the upper duct (7) is expelled from the converter through the fans (8).

1. A power converter for outdoor use comprising at least a first cabinet having an air inlet (1) and a second cabinet having an air outlet (2) that surround a cell cabinet (3) having a plurality of power cells (3a), wherein the air inlet (1) comprises a sand trap (5); a cold air stream (9) from outside the converter passes from the air inlet (1) to the cells (3a) through a cyclonic air filter (6); and wherein a warm air stream (10) from the cells (3a) is expelled through the air outlet (2), and characterized in that the cyclonic filter (6) comprises a tubular duct with an inner geometry formed by helical-shaped blades such that when the air passes through the blades, driven by an associated centrifugal fan, the dirt present in the air is centrifuged therein, being collected through a duct and expelled to the outside and in that the warm air (10) is expelled through an upper duct (7) incorporating at least one fan (8) located in the air outlet (2).

2. (canceled)
